(19) United States
(12) Patent Application Publication
(10) Pub. No.: US 2006/0240671 A1
(43) Pub. Date: Oct. 26, 2006

(54) METHOD OF REDUCING OUTGASSING POLLUTION

(76) Inventor: Shao-Chi Chang, Hsinfong Hsiang (TW)

Correspondence Address: NORTH AMERICA INTELLECTUAL PROPERTY CORPORATION, P.O. BOX 506, MERRIFIELD, VA, 22116, US

(21) Appl. No.: 11/307,991

(22) Filed: Mar. 2, 2006

Related U.S. Application Data
(62) Division of application No. 10/907,922, filed on Apr. 21, 2005.

(51) Int. Cl. H01L 21/302

(52) U.S. Cl. 438/689

(57) ABSTRACT

A method for reducing outgassing pollution in a semiconductor process includes matching a pressure of a VCE with a pressure of a process chamber before reaction gas is injected into the process chamber, injecting the reaction gas into the process chamber, opening a partitioning door disposed between the VCE and the process chamber, and extracting from the VCE gas formed by a reaction between residual reaction gas on a wafer surface and gas in the VCE through an exhaust of the VCE.

### CROSS REFERENCE TO RELATED APPLICATIONS

This application is a division of U.S. application Ser. No. 10/907,922 filed Apr. 21, 2005, and incorporated herein by reference in its entirety.

### BACKGROUND OF THE INVENTION

1. Field of the Invention

The present invention relates to a semiconductor apparatus and a method, and more particularly, to a semiconductor apparatus and a method capable of reducing outgassing pollution.

2. Description of the Prior Art

In a microelectronic fabrication process, etching is used to remove certain material from the wafer surface. There are two common approaches used in an etching process: wet etching and dry etching. In the dry etching process, different types of gas are used as etching materials, upon which plasma activation provides etchant species capable of removing certain material from the wafer. Dry etching, also called plasma etching, can by the anisotropic etching type which provides a much faster etching rate in the perpendicular direction than in the lateral direction. The etching gas chemistry in combination with the plasma is ideally chosen to be highly selective in order to etch certain material through the photoresist openings in a highly anisotropic manner without appreciably etching the photoresist itself. With better precision and better process control, dry etching is vastly adopted in the semiconductor wafer processing.

A plasma etching apparatus generally etches polymer, oxide or metal layers using plasmas generated by the glow discharge at a low temperature, thereby forming the large-scale integrated devices. The plasma etching apparatus widely includes a process chamber, a gas-feeding member and a voltage supply. The process chamber is a sealed container containing reaction gases, and the gas-feeding member introduces reaction gases into the process chamber. The voltage supply is connected to electrodes inside the process chamber and applies a radio frequency (RF) power to generate plasmas in the plasma chamber. The reaction gases from the gas-feeding member are converted into the plasmas in the process chamber by the electrodes.

Most current plasma etch processes employ a Standard Mechanical Interface (SMIF) that includes wafer cassettes, load port transfers (LPT), robots, automated material handling systems (AMHS), carrier ID systems, etc. A sealed and clean environment is essential in any semiconductor wafer processing. Simply speaking, the traditional concept is to dispose all semiconductor equipment in a clean room, while in the SMIF concept each semiconductor apparatus has its own clean room. Therefore, the SMIF-based technology provides better protection for the products from contamination. Usually in a SMIF-based plasma etching process, a wafer is firstly loaded into a vacuum cassette elevator (VCE) of a semiconductor apparatus. After the pressures of the VCE and the process chamber have been lowered to respective values, the partitioning door between the VCE and the process chamber is opened and the wafer is loaded into the process chamber. Depending on the type of the process, the process chamber is pumped to the prerequisite pressure before the etching gas is injected. Then the RF power of the etching apparatus is turned on and the etching process thus begins. After the etching process is completed, the RF power is turned off and the resultant gas is extracted from the process chamber. The partitioning door is again opened and the wafer is loaded into the VCE. Then inert gas, usually nitrogen, is pumped into the VCE for restoring the pressure of the VCE and finally the wafer is unloaded.

In the prior art plasma etch process, when the partitioning door is opened after the process in the process chamber is completed, the residual reaction gas on the wafer surface and the gas in the VCE bring another chemical reaction, resulting in pollutants that contaminate the VCE and the SMIF panels. This kind of outgassing pollution due to the second reaction between the residual reaction gas on the wafer surface and the gas in the VCE not only influence the cleanliness of the VCE and the SMIF panels, it may also contaminate the wafer surface. The pollutants from the second reaction can also react with the wafer again, resulting in an undesired over-etching or formation of new materials, and thus affect the quality of the process.

### SUMMARY OF THE INVENTION

It is therefore a primary objective of the claimed invention to provide a method capable of reducing outgassing pollution.

The claimed invention discloses a method capable of reducing outgassing pollution in a semiconductor process. The method includes matching a pressure of a VCE with a pressure of a process chamber before reaction gas is injected into the process chamber, injecting the reaction gas into the process chamber, opening a partitioning door disposed between the VCE and the process chamber, and extracting from the VCE gas formed by a reaction between residual reaction gas on a wafer surface and gas in the VCE through an exhaust of the VCE.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a semiconductor apparatus according to the present invention.

FIG. 2 is an enlarged diagram of a VCE in FIG. 1.

FIG. 3 is a diagram illustrating the VCE in conjunction with a first air-extracting device, a second air-extracting device and an air-pumping device.

FIG. 4 is a flow chart illustrating the method according to the present invention.

### DETAILED DESCRIPTION

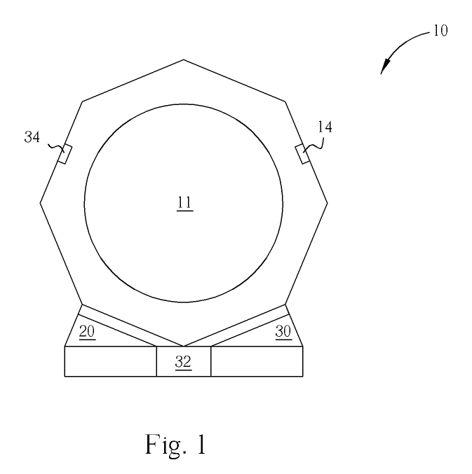

Please refer to FIG. 1 for a diagram illustrating a semiconductor apparatus 10 according to the present invention. The semiconductor apparatus 10 includes a process chamber 11, two vacuum cassette elevators (VCE) 20 and 30, and a control device 32. The process chamber 11 has a gas inlet 34, through which the reaction gas can be injected into the process chamber 11, and a first exhaust 14, through which the gas in the process chamber 11 can be extracted. The VCE 20 and VCE 30 are coupled to the process chamber 11, and a wafer can be loaded into the process chamber 11 either through the VCE 20 or the VCE 30. Since most semiconductor apparatuses have two VCEs, the VCE 20 is used hereafter to illustrate the embodiments of the present invention. Although the VCE 30 is not described in detail in the following paragraphs, since the VCE 20 and the VCE 30 have identical structures, the embodiments of the present invention on the VCE 20 can also be implemented on the VCE 30.

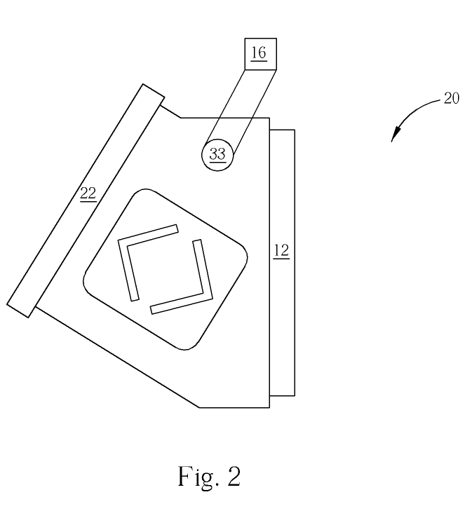

Please refer to FIG. 2 for an enlarged diagram of the VCE 20 in FIG. 1. The VCE 20 in FIG. 2 includes a first door 12, a second door 22 and a second exhaust 33. The first door 12 is disposed between the VCE 20 and the process chamber 11. A wafer can be loaded from the VCE 20 into the process chamber after opening the first door 12. The second door 22 is disposed between the VCE 20 and the ambient environment. The wafer can be loaded from the ambient environment into the VCE 20 after opening the second door 22. The second exhaust 33 is disposed in the VCE 20 and coupled to a first air-extracting device 16. The control device 32 in FIG. 1 controls the opening of the first air-extracting device 16 and the first door 12.

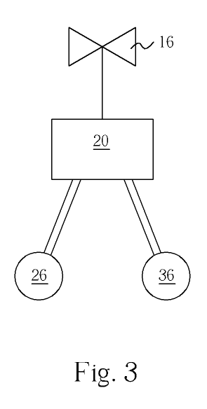

Please refer to FIG. 3 for a diagram illustrating the VCE 20, the first air-extracting device 16, a second air-extracting device 26 and an air-pumping device 36. The first air-extracting device 16 is coupled to the second exhaust 33 in the FIG. 2 and is controlled by the control device 32 in FIG. 1. When the first air-extracting device 16 is turned on, the gas in the VCE 20 is extracted through the second exhaust 33. Before the wafer is loaded into the process chamber 11 from the VCE 20, the second air-extracting device 26 extracts gas from the VCE 20 for matching the pressure of the VCE 20 with the pressure of the process chamber 11. After the process is completed, the pressure of the VCE 20 is raised to a predetermined value by the air-pumping device 36, and then the wafer can be unloaded. The first air-extracting device 16 can be an isolation valve, the second air-extracting device 26 can be a dry pump, and the air-pumping device 36 can inject nitrogen into the VCE 20.

The embodiment illustrated in FIG. 1 through FIG. 3 can be a transformer coupled plasma (TCP) etching apparatus. A TCP etching apparatus is a high density plasma (HDP) etching tool that provides high density plasma under low operational voltage and thus more complete ionization of reaction gases. Therefore a TCP etching apparatus offers faster and more thorough chemical reactions than etching tools using other techniques. However the present invention is not limited to a TCP etching apparatus. The present invention can be implemented on any semiconductor apparatus in which, when opening the first door 12 after the process is completed, a second chemical reaction between the residual reaction gas on the wafer surface and the gas in the VCE produces outgassing pollution.

Herein a method capable of reducing outgassing pollution in a semiconductor process according to the present invention is described in detail. When a process is performed on the semiconductor apparatus 10, the second door 22 is firstly opened for loading a wafer into the VCE 20. Then the second door 22 is closed and the second air-extracting device 26 is turned on to lower the pressure of the VCE 20 so that the pressure of the VCE 20 matches that of the process chamber 11 before the reaction takes place. When the pressure of the VCE 20 reaches a predetermined value, the first door 12 is opened for loading the wafer into the process chamber 11. After the wafer is in position, the first door 12 is closed and the vacuum of the process chamber 11 is further increased, depending on the process to be executed. When the pressure of the process chamber 11 reaches the prerequisite value, the reaction gas is injected into the process chamber 11 through the gas inlet 34 and the RF power of the semiconductor apparatus 10 is turned on. The reaction gas, ionized by the RF power and converted into plasma, then reacts with the wafer. At the same time the gas in the process chamber 11 is extracted through the first exhaust 14. After the process is completed, the first door 12 and the first air-extracting device 16, controlled by the control device 32, are opened simultaneously. When the first door 12 is opened, the residual reaction gas on the wafer surface tends to undergo a second chemical reaction with the gas in the VCE and produces pollutants that contaminate the VCE 20. The method in the present invention removes the undesired pollutants from the VCE 20 by the first air-extracting device 16 controlled by the controlled device 32. Therefore the outgassing pollution can be reduced in the present invention. Finally, the air-pumping device 36 injects inert gas, usually nitrogen, into the VCE 20 for raising the pressure of the VCE 20 to a certain value, usually to one atmospheric pressure, and then the wafer can be unloaded.

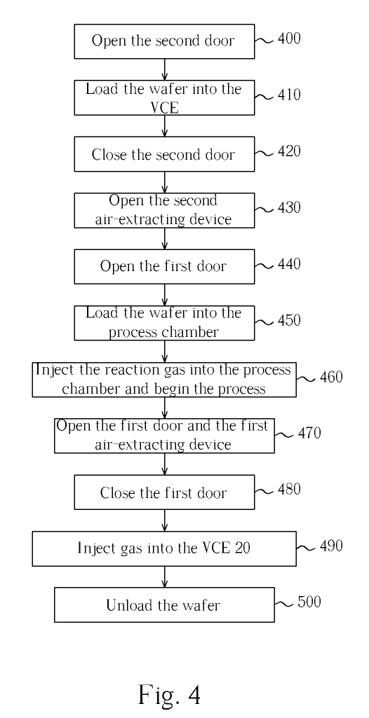

Please refer to FIG. 4 for a flow chart illustrating a method of the present invention implemented on the semiconductor apparatus 10. The flow chart in FIG. 4 includes the following steps:

Step 400: open the second door 22;

Step 410: load the wafer into the VCE 20;

Step 420: close the second door 22;

Step 430: open the second air-extracting device 26

Step 440: open the first door 12;

Step 450: load the wafer into the process chamber 11;

Step 460: inject the reaction gas into the process chamber 11 through the gas inlet 34, and turn on the power of the semiconductor apparatus 10;

Step 470: open the first door 12 and the first air-extracting device 16 and extract from the VCE 20 gas formed by a reaction between residual reaction gas on the wafer surface and gas in the VCE 20 through the second exhaust 33;

Step 480: close the first door 12;

Step 490: inject gas into the VCE 20 by the air-pumping device 36; and

Step 500: unload the wafer.

In the step 470, the control device 32 controls the opening of the first door 12 and the first air-extracting device 16. In the embodiment of the present invention illustrated by the flow chart in FIG. 4, the first door 12 and the first air-extracting device 16 are opened simultaneously. However, the present invention is not limited to simultaneously opening the first door 12 and the first air-extracting device 16. After the process in the process chamber 11 is completed, the first air-extracting device 16 can be turned on before the first door 12 is opened; or the first air-extracting device 16 can be turned on shortly after the first door 12 is opened. The present invention includes any method that uses the first air-extracting device 16 to extract from the VCE 20 gas formed by a reaction between residual reactive gas on a wafer surface and gas in the VCE 20.

The method of the present invention illustrated in FIG. 4 can be implemented on a semiconductor etching process that uses hydrogen bromide (HBr) as the reaction gas. Since HBr is very reactive with the gas in the VCE 20, the present invention provides an effective approach capable of reducing the outgassing pollution in an etching process using HBr as the reaction gas. However the present invention is not limited to a HBr-based etching process. The present invention can be implemented on any process in which the residual reaction material left on the wafer surface reacts with the gas in the VCE 20 when opening the first door 12 after the process in the process chamber 11 is completed.

In the prior art semiconductor process, when the first door 12 is opened after the process in the process chamber 11 is completed, the residual reaction gas on the wafer surface reacts with the gas in the VCE 20, resulting in pollutants that contaminate the VCE 20 and the SMIF panels. The outgassing pollution due to this second reaction between the residual reaction gas on the wafer surface and the gas in the VCE 20 not only influence the cleanliness of the VCE 20 and SMIF panels, it may also contaminate the wafer surface. The materials formed by the second reaction can also react with the wafer again, resulting in an undesired over-etching or formation of new materials, and thus affect the quality of the process. Compared to the prior art, the present invention provides a semiconductor apparatus and method capable of reducing outgassing pollution. By opening the first air-extracting device 16 and the first door 12 using the control device 32, the pollutants from the second reaction can be extracted from the VCE 20 through the third exhaust 33 of the VCE 20. Therefore the present invention can effectively reduce outgassing pollution and improve the quality of the semiconductor process.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method capable of reducing outgassing pollution in a semiconductor process including:
(a) matching a pressure of a VCE with a pressure of a process chamber before reaction gas is injected into the process chamber;
(b) injecting the reaction gas into the process chamber;
(c) opening a partitioning door disposed between the VCE and the process chamber; and
(d) extracting from the VCE gas formed by a reaction between residual reaction gas on a wafer surface and gas in the VCE through an exhaust of the VCE.

2. The method of claim 1 wherein step (c) and step (d) are executed at the same time.

3. The method of claim 1 wherein step (c) and step (d) are executed after step (b).

4. The method of claim 1 further including step (e):
injecting gas into the VCE for raising the pressure in the VCE to a predetermined value after step (d).

5. The method of claim 4 wherein step (e) injects nitrogen into the VCE for raising the pressure in the VCE to a predetermined value after step (d).

6. The method of claim 1 wherein step (b) injects hydrogen bromide into the process chamber.

7. The method of claim 1 being applied to an etching process of the semiconductor processing.
